(19) United States
(12) Patent Application Publication
(10) Pub. No.: US 2016/0190372 A1
(43) Pub. Date: Jun. 30, 2016

(54) SOLAR COLLECTOR DEVICE

(71) Applicant: YUN-MIN WANG, Taichung City (TW)

(72) Inventor: YUN-MIN WANG, Taichung City (TW)

(21) Appl. No.: 14/955,581

(22) Filed: Dec. 1, 2015

(30) Foreign Application Priority Data
Dec. 24, 2014 (TW) 103222862

(51) Int. Cl. H01L 31/054; G02B 19/00

(52) U.S. Cl. CPC H01L 31/0547; G02B 19/0028; G02B 19/0019; G02B 19/0042; H01L 31/0543

(57) ABSTRACT

A solar collector device is used for concentrating sunlight rays to a light energy conversion unit to increase entering amount of light of the light energy conversion unit. The light energy conversion unit has a light receiving surface located on a reference plane. The solar collector device includes at least two reflecting devices which are used for reflecting the sunlight rays on the light receiving surface. The two reflecting devices are respectively disposed at two opposite sides of the light receiving surface. The two reflecting devices respectively have a plurality of reflective surfaces which are connected with each other, wherein the reflective surfaces have different inclination angles between each of the reflective surfaces and the reference plane.

### BACKGROUND OF THE INVENTION

1. Field of the Invention

The instant disclosure relates to a solar collector device, and particularly, to a solar collector device being used for improving solar power efficiency on a solar cell or on a concentrating solar thermal power generation system.

2. Description of Related Art

At present, solar cells are the mainstream in the solar power technology. But, biggest problem the solar cell faces is that, a photoelectric conversion efficiency of the solar cell is inferior, so as to cause insufficient electricity generation efficiency. For this reason, lots of solar panels are used to generate currents in a conventional solar power system, and it is costly.

In order to solve the problem of the solar cell having inferior photoelectric conversion efficiency, materials and manufacturing processes used in the solar cell of the conventional solar power system have been continuously modified to improve the photoelectric conversion efficiency, but breakthroughs are difficult. For example, using a III group material or a V group material to form a multilayer structure in the solar cell that has high photoelectric conversion efficiency. However, the multilayer structure of the III/V group material has to be cooperatively used with a fresnel lens and a biaxial tracking system, and extremely high precision is required therein to generate effective magnification. Otherwise, the effective magnification would be sharply decreased and it is still costly. Thus, a light collector device such as reflective plate or lens is gradually used to cooperate with the tracking system to increase the amount of sunlight passing through into such a silicon solar cell, so as to upgrade the photoelectric conversion efficiency.

In addition to the solar cells, a concentrated solar power (CSP) has been being developed at present. The CSP is a heat collector type solar power system. Reflectors or lenses are used to collect sunlight rays from a larger area to a relative tiny light collecting area to concentrate the sunlight rays based on optical principles. Accordingly, the light collecting area on a power generator is irradiated by sunlight to increase its temperature, a solar energy is converted into a heat energy based on photothermal conversion principles, and the heat energy then drives the power generator to generate electric power through a heat engine such as steam turbine engine.

In the abovementioned solar power system or concentrated solar power system, the reflective plate is usually used to concentrate the sunlight rays. FIG. 13, a model of conventional reflective type solar collector device, shows the basic structure and principle therein. The conventional reflective type solar collector device includes a plurality of reflective plates 3 aslant disposed at sides of a light energy conversion unit 1, and the reflective plates 3 are used to reflect the sunlight rays on a light receiving surface 2 of the light energy conversion unit 1. Via a reflecting action of the reflective plates 3, the sunlight rays outside of a range of the light receiving surface 2 of the light energy conversion unit 1 can be reflected on the light receiving surface 2 of the light energy conversion unit 1.

The light collection efficiency of the conventional reflective type solar collector device can be defined as an area of the effective light collecting area relative to an area of the light receiving surface 2 of the light energy conversion unit 1. When the effective light collecting area assembled by the reflective plates 3 (which is the area surrounded by each of the reflective plates 3 having a top opening) is larger, more sunlight rays can be concentrated on the light receiving surface 2 of the light energy conversion unit 1, so as to upgrade the amount of sunlight effectively passing through. Therefore, if the area of the effective light collecting area of the reflective plates 3 is increased, sunlight rays in a wider range can be concentrated on the light receiving surface 2 of the light energy conversion unit 1, and then the light collection efficiency of the light collector device can be increased.

In FIG. 13, a pair of reflective plates 3 are upwardly and outwardly aslant disposed at a periphery of the light receiving surface 2 of the light energy conversion unit 1, when the light receiving surface 2 of the light energy conversion unit 1 faces to the sunlight, the sunlight rays irradiate on the light receiving surface 2 of the light energy conversion unit 1 along a direction of optical axis a, and the optical axis a and the light receiving surface 2 are perpendicular with each other. Since the sun can be seen as an infinite far light source, an incident light ray L1 having a traveling direction projected on the reflective surface of the reflective plates 3 also can be seen as being parallel with the optical axis a. The incident light ray L1 is reflected by the reflective plate 3 to form a reflected light ray L2 which is projected on the light receiving surface 2. Based on the reflection principle, when a light ray irradiates on a plane, an incident angle is equal to a reflection angle. Hence, an included angle θ1 between the incident light L1 and the reflective surface of the reflective plate 3 also would be equal to an included angle θ2 between the reflective light L2 and the reflective surface of the reflective plate 3. When the reflective surface of the reflective plate 3 is a flat shape, a light angle reflected from each of the positions of the reflective surface of the reflective plate 3 is identical to the included angle θ2 between the reflective light L2 and the reflective surface of the reflective plate 3.

However, in relation to the position of the reflective plate 3 irradiated by the sunlight rays being closer to an upper site on the reflective plate 3, the position of the light receiving surface 2 where the light rays reflected by the reflective plate 3 projects on is further away from an intersection of the light receiving surface 2 and the reflective plate 3. Therefore, when a height H of the reflective plate 3 is higher than a certain height, a projection point of the light ray reflected by the reflective plate 3 is located outside of the light receiving surface 2. As shown in FIG. 13, a reflected light ray L4 is a light reflection path that an incident light ray L3 incidented from the topmost edge of the reflective plate 3 is reflected by the reflective plate 3 to project on a most marginalized position of the light receiving surface 2. Thus, when the height of the reflective plate 3 is higher than a height of an intersection position of the reflected light ray L4 and the reflective plate 3 in FIG. 13, a part of light rays reflected by the reflective plate 3 are located outside of the reflected light ray L4, that is, the reflected light rays are located outside of the light receiving surface 2, and cannot project onto the light receiving surface 2 of the light energy conversion unit 1, so as to be unable to generate electricity power through the light energy conversion unit 1.

Referring to FIG. 13, due to the height of the reflective plate 3 being higher than the intersection of the reflected light ray L4 being an invalid reflective surface, such that an effective collecting height H is defined as the height range between the light receiving surface 2 of the light energy conversion unit 1 and the intersection of the reflective plate 3 and the reflected light ray L4, an effective collecting width W is defined as a space between the two intersections where the two reflective plates 3 are located at. According to the above, if the effective collecting width W of the reflective plate 3 is bigger, the light collector device has higher light collecting efficiency. Therefore, the effective collecting width W of the reflective plate 3 can be increased by modifying the relative inclination angle α between the reflective plate 3 and the light receiving surface 2.

The conventional reflective type solar collector device is further analyzed (shown in FIG. 13). Based on the light reflection principle, the included angle θ1 between the incident light L1 and the reflective plate 3 is equal to the included angle θ2 between the reflective light L2 and the reflective plate 3. Thus, if the relative inclination angle α between the reflective plate 3 and the light receiving surface 2 is equal to 45 degrees, the included angle between the light reflection path of reflected light ray L2 and the incident light ray L1 is equal to 90 degrees, and the reflective light L2 and the light receiving surface 2 are parallel with each other so as to be unable to be projected onto the light receiving surface 2. When the relative inclination angle α between the reflective plate 3 and the light receiving surface 2 is larger than 45 degrees, the reflected light ray L2 reflected by the reflective plate 3 starts to be projected onto the light receiving surface 2.

Please refer to FIGS. 14A and 14B, which shows an influence of the relative inclination angle α between the reflective plate 3 and the light receiving surface 2 affected by the effective collecting height H and the effective collecting width W. When the light receiving surface 2 of the light energy conversion unit 1 has a fixed width, as the relative inclination angle α between the reflective plate 3 and the light receiving surface 2 is gradually increased (which is the reflective plate 3 being gradually tilted from 45 to 90 degrees), the effective collecting width W of the reflective plate 3 would be gradually increased, but the effective collecting height H is also increased. At the same time, as shown in FIGS. 14A and 14B, when the relative inclination angle α between the reflective plate 3 and the light receiving surface 2 is increased, an increase rate of the effective collecting width W would be gradually smaller than an increase rate of the effective collecting height H. Even when the relative inclination angle α between the reflective plate 3 and the light receiving surface 2 is larger than 75 degrees, the effective collecting height H is rapidly increased accompanied with the increasing rate of the relative inclination angle α so as to cause the effective collecting height H and the effective collecting width W having a great disparity.

Therefore, according to the abovementioned description, the increase rate of the effective collecting width W of the conventional reflective type solar collector device is limited by geometry, so that the increase rate of the effective collecting width W cannot be substantially increased. Otherwise, the reflective plate 3 will have excess height to cause the light collector device to have a bulky volume, and further increase the setting cost.

For these reason, how to upgrade the light collection efficiency of the solar collector device by modifying the structure design of the reflective plate 3 to further overcome the abovementioned drawbacks has become one of the important issues in this industry.

### SUMMARY OF THE INVENTION

A reflective plate is used to collect sunlight rays in a conventional solar collector device, if an effective collecting width is increased, it would cause a height of the reflective plate to be rapidly increased, so as to restrict an elevation of light collection efficiency of the reflective plate. Accordingly, an embodiment of the instant disclosure provides a solar collector device to overcome the abovementioned problem.

In the embodiment of this instant disclosure, a light reflecting side of the reflective plate is composed of a plurality of reflective surfaces which are connected with each other. There are different inclination angles between each of the reflective surfaces and a light receiving surface of a light energy conversion unit, and each of the reflective surfaces can reflect and project the sunlight rays perpendicularly to the light receiving surface in an identical projection area of the reflective surface, so that the sunlight rays projected on the reflective surface would concentrate on the light receiving surface of the light energy conversion unit.

The solar collector device of the instant disclosure includes a light energy conversion unit and at least two reflecting devices. The light energy conversion unit can be a solar panel or a photothermal conversion device being used for a concentrated solar power (CSP) system. The light energy conversion unit has a light receiving surface. The two reflecting devices are respectively disposed at two opposite sides of the light receiving surface. The two reflecting devices respectively have a plurality of reflective surfaces which are connected with each other, wherein the reflective surfaces have different inclination angles between each of the reflective surfaces and the light receiving surface, and the relative inclination angle between each of the reflective surfaces and the light receiving surface ranges from 45 to 90 degrees. Each of the reflective surfaces respectively has different heights and different inclination angles, and the heights and the inclination angles of each of the reflective surfaces are arranged to let each of the reflective surfaces be able to reflect the sunlight rays in an identical projection area of the light receiving surface of the light energy conversion unit.

In the embodiment of this instant disclosure, in the plurality of reflective surfaces of each of the reflecting device, the reflective surface closest to the light receiving surface has a smallest inclination angle (but the inclination angle is larger than 45 degrees), the reflective surface remotest from the light receiving surface has a largest inclination angle (but the inclination angle of the last end of the reflective surface is smaller than 90 degrees), and the inclination angle of each of the reflective surfaces is smaller than the inclination angle between the reflective surface and the next reflective surface adjacent to the reflective surface.

This instant disclosure has an advantage in that, since the reflecting device is composed of the plurality of reflective surfaces having different inclination angles, the reflecting device of this instant disclosure can overcome the conventional reflective plate having the reflective surfaces with the same inclination angle, a width of top opening of the reflective plate is limited by the included angle between the reflective plate and the light receiving surface, and limitation of the width of light receiving surface of the light energy conversion unit, to achieve an increase of the width of the top opening of the reflective plate under the limited heights of the reflective plate, so as to increase an area of effective collecting area, and further enhance a light collection efficiency of the solar collector device.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a schematic structure view of a solar collector device of a first embodiment in the instant disclosure;

FIG. 2 shows a perspective exploded view of a solar collector device of a first embodiment in the instant disclosure;

FIG. 3 shows a plan view of a solar collector device of a first embodiment in the instant disclosure;

FIG. 4 shows a plan view of a solar collector device of a second embodiment in the instant disclosure;

FIG. 5 shows a plan view of a solar collector device of a third embodiment in the instant disclosure;

FIG. 6 shows a perspective assembled view of a solar collector device of a third embodiment in the instant disclosure;

FIG. 7 shows a combination of cross-sectional view of a solar collector device of a fourth embodiment in the instant disclosure;

FIG. 8 shows a schematic structure view of a solar collector device of a fifth embodiment in the instant disclosure;

FIG. 9 shows a plan view of a solar collector device of a sixth embodiment in the instant disclosure;

FIG. 10 shows a perspective assembled view of a solar collector device of a sixth embodiment in the instant disclosure;

FIG. 11 shows a plan view of a solar collector device of a seventh embodiment in the instant disclosure;

FIG. 12 shows a schematic structure view of a solar collector device of a seventh embodiment in the instant disclosure;

FIG. 13 shows a schematic structure view of a solar collector device of prior art; and

FIGS. 14A and 14B shows a schematic structure view of a relationship between an inclination angle of a reflective plate of a solar collector device and an effective collecting height in prior art.

### DETAILED DESCRIPTION OF THE PREFERRED EMBODIMENTS

Embodiments disclosed in the instant disclosure are illustrated via specific examples as follows, and people familiar in the art may easily understand the advantages and efficacies of the instant disclosure by the disclosure of the specification. The instant disclosure may be implemented or applied by other different specific examples, and each of the details in the specification may be applied based on different views and may be modified and changed under the existence of the spirit of the instant disclosure. The figures in the instant disclosure are only for brief description, but they are not depicted according to actual size and do not reflect the actual size of the relevant structure. The following embodiments further illustrate related technologies of the instant disclosure in detail, but the scope of the instant disclosure is not limited herein.

### First Embodiment

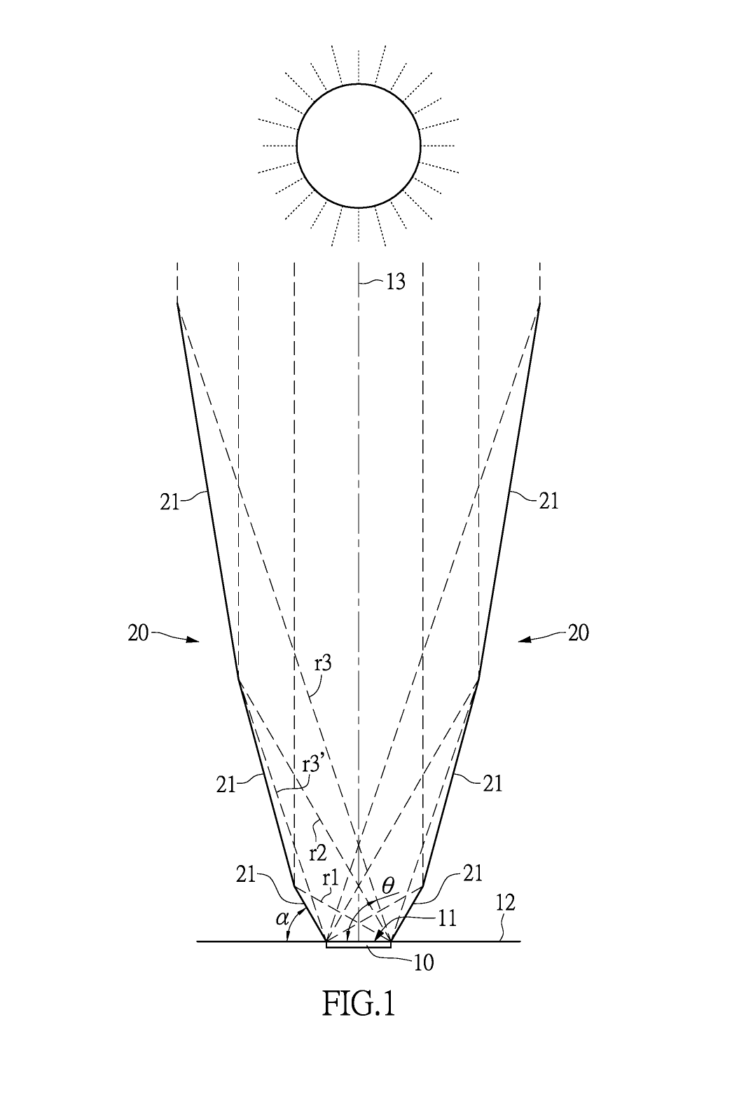

Please refer to FIGS. 1 to 3. A solar power device of this instant disclosure has a solar collector device which includes a light energy conversion unit 10 and at least two reflecting devices 20. The light energy conversion unit 10 that can be a solar panel or a photothermal conversion device (e.g., heat absorber plate) used for a concentrated solar power (CSP) system. The light energy conversion unit 10 has a light receiving surface 11 located on a reference plane 12. Sunlight rays can directly irradiate on the light receiving surface 11, or can be reflected on the light receiving surface 11 by the reflecting device 20, and the sunlight rays can be converted into electric energy or heat energy to generate electric power through the light energy conversion unit 10.

FIG. 1 shows a schematic structure view of a solar collector device of a first embodiment in the instant disclosure. The solar collector device of the first embodiment in the instant disclosure includes at least two reflecting devices 20, and the two reflecting devices 20 are respectively disposed at two opposite sides of the light receiving surface 11 of the light energy conversion unit 10. The two reflecting devices 20 respectively have a plurality of reflective surfaces 21 which are connected with each other, and are used for reflecting the sunlight rays on the light receiving surface 11 of the light energy conversion unit 10.

For ease of explanation, the subsequent terms in the specification such as a height of the reflective surfaces 21, an inclination angle of the reflective surface 21, and a projection area of a reflective light are defined in the following paragraph. In this specification, the height of the reflective surfaces 21 is defined as, from a side perspective of the reflecting device 20, the distance between two endpoints which are generated from each of the different reflective surfaces 21 being along a direction perpendicular to the light receiving surface 11. The inclination angle of the reflective surface 21 is defined as, an included angle between each of the reflective surfaces 21 and the reference plane 12 disposed at the light receiving surface 11. The projection area is defined as, when the sunlight rays are perpendicular to the light receiving surface 11, and the sunlight rays are reflected by the reflective surface 21 to project onto the light receiving surface 11 to form a light projection range.

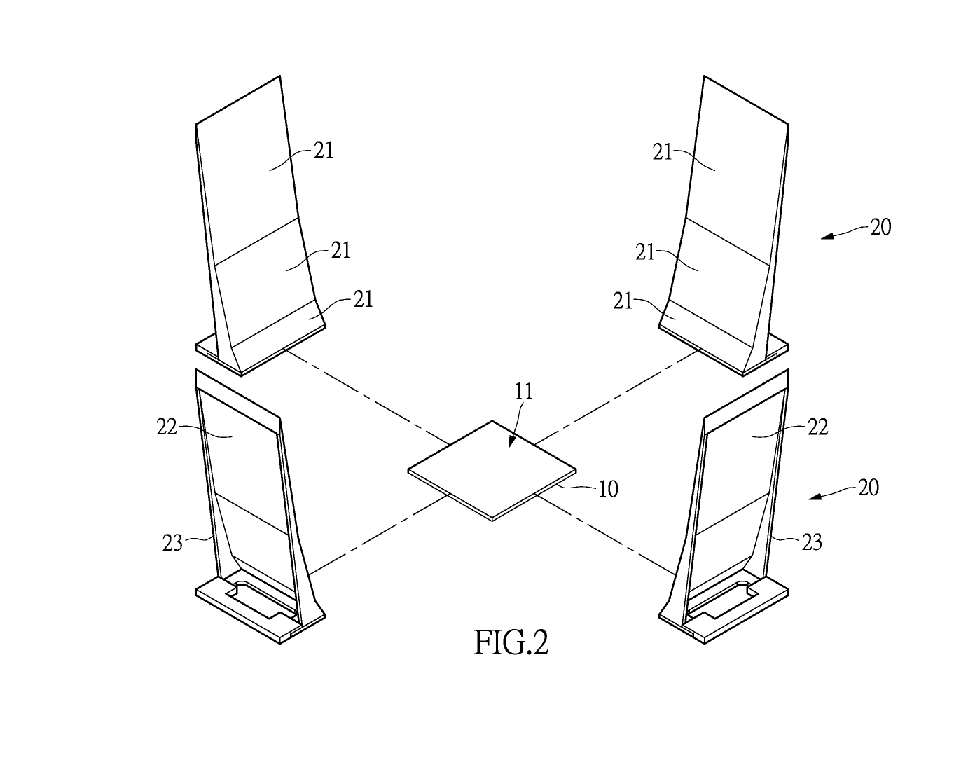

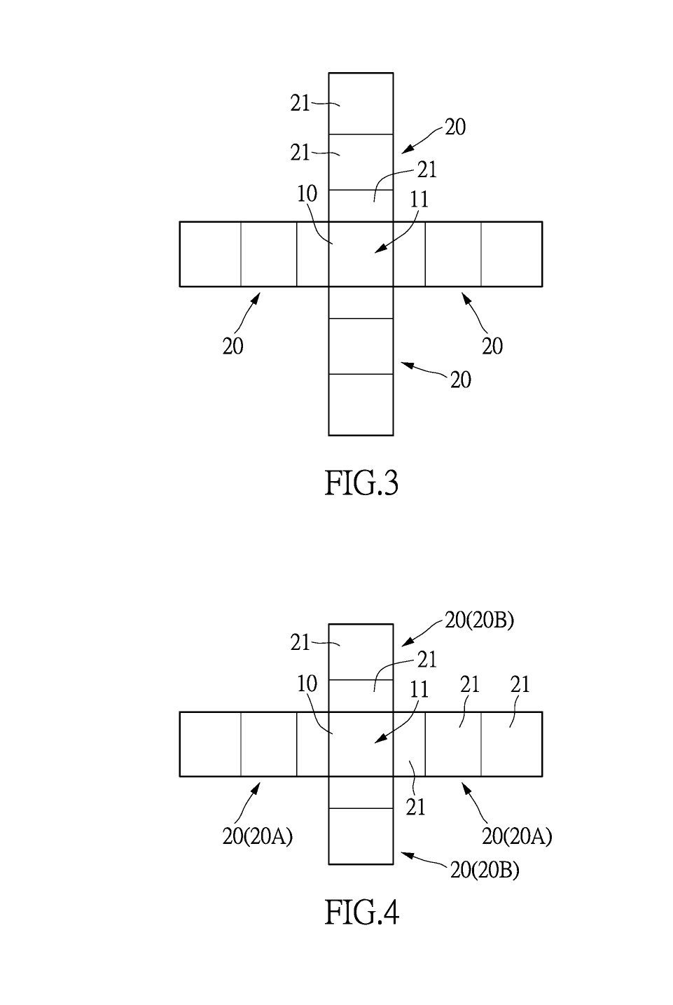

Each of the reflective surfaces 21 of the reflecting device 20 of this instant disclosure respectively has different heights and different inclination angles between each of the reflective surfaces 21 and the reference plane 12. The heights and the inclination angles of each of the reflective surfaces 21 are arranged to let each of the reflective surfaces 21 be able to cooperatively reflect the sunlight rays which are perpendicular to the light receiving surface 11 in an identical projection area of the light receiving surface 11 of the light energy conversion unit 10. Meanwhile, as shown in FIGS. 2 and 3, each of the reflective surfaces 21 of the reflecting device 20 of this instant disclosure and the light receiving surface 11 of the light energy conversion unit 10 have an identical width, thus the sunlight rays can be reflected on the light receiving surface 11 by each of the reflective surfaces 21 in a direction perpendicular to a side edge of the light receiving surface 11, so as to form a rectangular projection area on the light receiving surface 11.

Each of the reflective surfaces 21 of the reflecting device 20 of this instant disclosure is designed to have a rectangular plane with a width that is identical to the width of the light receiving surface 11, so that the sunlight rays reflected by each of the reflective surfaces 21 can form a rectangular projection area on the light receiving surface 11, and the sunlight rays reflected by each of the reflective surfaces 21 can be evenly distributed on the light receiving surface 11.

As shown in FIG. 1, since the projection area formed by each of the reflective surfaces 21 is correlated to the inclination angle and height of each of the reflective surfaces 21, each of the reflective surfaces 21 of the reflecting device 20 of this instant disclosure is arranged to have different heights and inclination angles to let the projection areas formed by each of the reflective surfaces 21 be cooperatively located in the identical area on the light receiving surface 11 (which are the projection areas formed by each of the reflective surfaces 21 overlapped with each other).

A specific arrangement way of the reflective surface 21 of the reflecting device 20 of this instant disclosure is further described as follows. Please refer to FIG. 1. Based on the light reflection principle, the inclination angle of each of the reflective surfaces 21 has to range from 45 to 90 degrees, such that the sunlight rays perpendicular to the light receiving surface 11 can be reflected on the light receiving surface 11. Therefore, the inclination angle of each of the reflective surfaces 21 in this instant disclosure is designed to range from 45 to 90 degrees.

As shown in FIG. 1, in the first embodiment, each of the reflecting devices 20 respectively has three different reflective surfaces 21. However, it must be emphasized that the number of the reflective surfaces 21 of the reflecting device 20 is not limited to the number disclosed in FIG. 1. Furthermore, the number of the reflective surfaces 21 can be increased or decreased depending on actual requirement. At the same time, each of the reflective surfaces 21 of the reflecting device 20 can be a planar reflective surface. When the reflecting device 20 is a planar shape, the sunlight rays can be evenly reflected and have the greatest reflection result, so that the sunlight rays reflected by reflective surface 21 can be projected on the light receiving surface 11 with average strength. However, in this instant disclosure, the reflective surface 21 also can be an arc with slight curvature, or have a wave surface. If the reflective surface 21 has an arc surface or a wave surface, a curvature of the reflective surface 21 must be controlled to not focus on the light receiving surface 11 of the light energy conversion unit 10 in such a way as to avoid the reflective light concentrated on the light receiving surface 11 causing a heat concentration phenomenon.

Please refer to FIGS. 1 and 2. Each of the reflective surfaces 21 of the reflecting device 20 of the first embodiment in this instant disclosure is a planar shape, based on the light reflection principle, and each of the sunlight rays projecting on different positions of the same reflective surface 21 can be reflected with the identical angle by the reflective surface 21. Therefore, as shown in FIG. 1, a light reflection path r3 and a light reflection path r3′ are both indicated by imaginary lines, representing that, when the sunlight rays project on the third positioned reflective surface 21 having an upper edge and a lower edge of the reflecting device 20, the light reflection paths are formed. Since the reflective surface 21 is a plane, the sunlight rays project on each of the positions of the reflective surface 21 can be seen as the light rays being parallel with each other, so that the light traveling path reflected by the sunlight rays through the same reflective surface 21 can be parallel with each other, and the light reflection paths r3 and r3′ shown in the figure also can be parallel with each other.

Simultaneously, a light reflection path r1 indicated by an imaginary line in FIG. 1 represents the light reflection path of the first positioned reflective surface 21 adjacent to the light receiving surface 11 in the plurality of reflecting devices 20. The light reflection path r2 indicated by an imaginary line represents the light traveling path reflected by the second positioned reflective surface 21.

The arrangement of the light reflection path of each of the reflective surfaces 21 of the reflecting device 20 in this instant disclosure is to let the sunlight rays reflected by each of the reflective surfaces 21 be projected on the identical projection area on the light receiving surface 11 together. Each of the reflective surfaces 21 should be avoid interfering in the light reflection path of another reflective surface 21 which is connected after the reflective surface 21. In the first embodiment of the instant disclosure, the projection area formed by the reflective light of each of the reflective surfaces 21 covers the whole area of the light receiving surface 11. In order to optimize the light reflection efficiency of each of the reflective surfaces 21, the inclination angle and height of each of the reflective surfaces 21 of this instant disclosure are adjusted to make the light traveling path reflected by the upper edge and the lower edge of each of the reflective surfaces 21 respectively pass through two side edges of the light receiving surface 11. For example, in the reflecting device 20 shown in FIG. 1, the light reflection paths r3, r3′ of the upper and lower edges of the third positioned reflective surface 21 respectively align with the two side edges of the light receiving surface 11, so that the projection area formed by the reflective light of the third positioned reflective surface 21 can exactly cover the whole light receiving surface 11.

In addition, in order to avoid the sunlight rays reflected by each of the reflective surfaces 21 interfering with other reflective surfaces 21 to cause loss of the sunlight rays, the inclination angle of each of the reflective surfaces 21 in this instant disclosure has to be arranged so that, the inclination angle of each of the reflective surfaces 21 is equal to or smaller than the inclination angle of the light reflection path of the sunlight rays reflected by the another reflective surface 21 adjacent to each of the reflective surfaces 21 having the upper edge (shown in FIG. 1). The inclination angle of the first positioned reflective surface 21 close to one end of the reflecting device 20 and the light receiving surface 11 is equal to or smaller than the inclination angle of the light reflection path of the second positioned reflective surface 21. In this embodiment, the inclination angle of the light reflection path r2 of the second positioned reflective surface 21 is arranged to be equal to the inclination angle of the first positioned reflective surface 21, and the reflective light of the second positioned reflective surface 21 can be projected on the light receiving surface 11 in a direction close to flat on a surface of the first positioned reflective surface 21. The inclination angle of third positioned reflective surface 21 has the same arrangement with the abovementioned way that, the inclination angles of the light reflection paths r3, r3′ of the third positioned reflective surface 21 are larger than the inclination angle of the second positioned reflective surface 21, such that the light reflection path of the third positioned reflective surface 21 can avoid interference of the second positioned reflective surface 21.

Therefore, the arrangement of the inclination angle of each of the reflective surfaces 21 of the reflecting device 20 can be generalized as follows:

1. First, the inclination angle of each of the reflective surfaces 21 of the reflecting device 20 is in a range from 45 to 90 degrees.

2. In the plurality of reflective surfaces 21 of each of the reflecting device 20, the reflective surface 21 being most adjacent to the light receiving surface 11 has the smallest inclination angle (but the inclination angle is larger than 45 degrees), the reflective surface 21 remotest from the light receiving surface 11 has a largest inclination angle (but the inclination angle of the last end of the reflective surface is smaller than 90 degrees), and the inclination angle of each of the reflective surfaces 21 is smaller than the inclination angle between the reflective surface 21 and the next reflective surface 21 adjacent to the reflective surface 21.

3. In the plurality of reflective surfaces 21 of each of the reflecting device 20, the inclination angle of each of the reflective surfaces 21 is equal to or smaller than the inclination angle of the light reflection path of the next reflective surface 21 adjacent to the reflective surfaces 21.

The abovementioned connection is in accordance with the following relationship: αₙ<αₙ₊₁, αₙ≦θₙ₊₁, and 45°<α<90°, where the symbols have the following meanings:

α represents the relative inclination angle between each of the reflective surfaces 20 and the reference plane 12;

θ represents the relative inclination angle between the light reflection path generated by the sunlight rays projecting on each of the reflective surfaces 21 and the reference plane 12;

n represents an order of an arrangement in a direction from each of the reflective surfaces 21 in the reflecting device 20 close to the light receiving surface 11 away from the light receiving surface 11, and n is a positive integer which is larger than or equal to 1 and smaller than total amount of the reflective surfaces 21 in each of the reflecting devices 20.

The technical principle of arrangement of the inclination angle and the height of each of the reflective surfaces 21 of the reflecting device 20 can be understood from FIG. 1. The plurality of reflective surfaces 21 of the reflecting device 20 of this instant disclosure are arranged via the abovementioned ways, such that the reflecting device 20 can break through the conventional reflective plate which is composed of the reflective surfaces having the identical inclination angle, a width of the top opening of the reflective plate is limited by the included angle between the reflective plate and the light receiving surface, and a limitation of the width of the light receiving surface of the light energy conversion unit, to achieve an increase of the width of the top opening of the reflective plate under the limited heights of the reflective plate, so as to increase an area of the effective collecting area, and further enhance a light collection efficiency of the solar collector device.

FIG. 2 shows a perspective exploded view of a solar collector device of a first embodiment in the instant disclosure. As shown in FIG. 2, two pairs of the reflecting devices are respectively disposed at four sides of the light energy conversion unit 10, each of the reflecting devices 20 is composed of at least one board member 22 and at least one supporting member 23 at a rear surface of the board member 22. The board member 22 having a width is equal to the width of the light receiving surface 11 of the light energy conversion unit 10, and the supporting members 23 are used for being disposed at the four sides of the light receiving surface 11 of the light energy conversion unit 10. As shown in FIG. 3, the four reflecting devices 20 of the first embodiment of this instant disclosure are disposed at a periphery of the light receiving surface 11 of the light energy conversion unit 10, when the four reflecting devices 20 are observed by a plan view that is represented a cross shape, each of the reflecting devices 20 in this embodiment respectively has the same width and height simultaneously.

The solar collector device of the first embodiment is composed of the four reflecting devices 20 which are respectively disposed at two opposite sides of the light energy conversion unit 10. Therefore, the light collection efficiency with two axes can be provided, and it can be cooperatively used with a biaxial tracking system (which is two axials of pitch and rotation).

### Second Embodiment

Please refer to FIG. 4. The solar collector device of the second embodiment includes four reflecting devices 20 disposed at four sides of a rectangular light energy conversion unit 10. At the same time, the four reflecting devices 20 can be divided into one pair of first reflecting devices 20A having higher height, and one pair of second reflecting devices 20B having lower height. Wherein, the two first reflecting devices 20A are disposed at the two opposite sides of the light energy conversion unit 10, and the two second reflecting devices 20B are disposed at other opposite sides of the light energy conversion unit 10.

The height of the second reflecting device 20B in the second embodiment is lower than the height of the first reflecting device 20A, and is adapted for a single-axis tracking system, or for a small power station being located in a metropolis having high cost of land. The biaxial tracking system also can be cooperatively used with the first and second reflecting devices 20A, 20B of the second embodiment depending on limitations of shapes and sizes of a place, so as to achieve the maximum power output.

### Third Embodiment

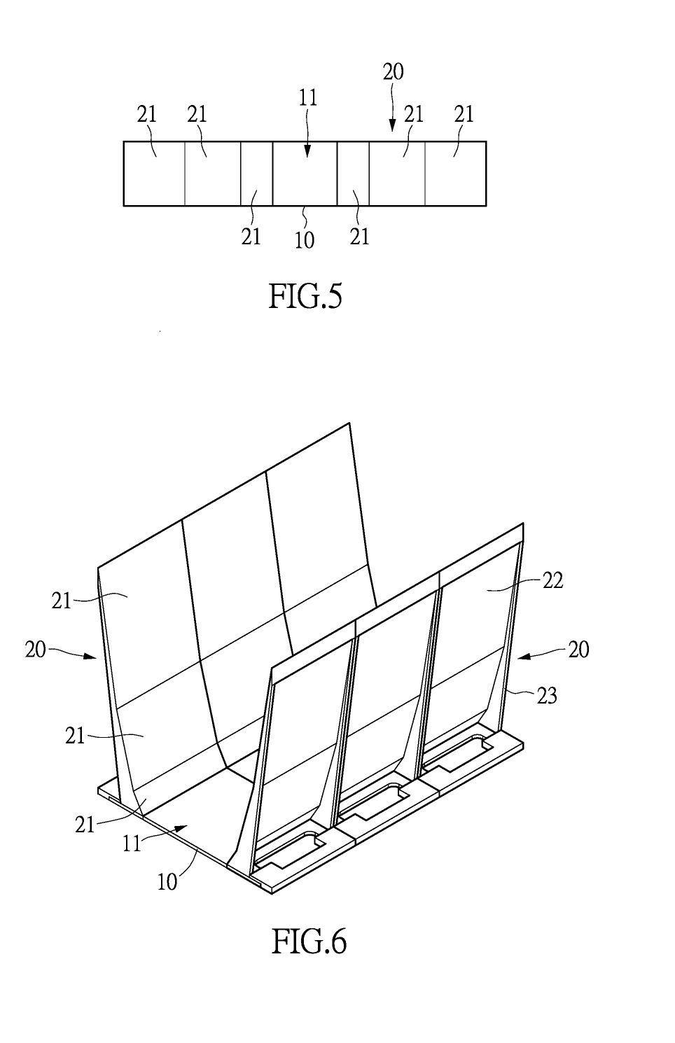

Please refer to FIGS. 5 and 6. The solar collector device of the third embodiment includes two reflecting devices 20 and one light energy conversion unit 10, wherein the two reflecting devices 20 are disposed at the two opposite sides of the light energy conversion unit 10.

The reflecting device 20 of the third embodiment can be only disposed at the two sides of the light energy conversion unit 10, and the light receiving surface 11 of the light energy conversion unit 10 has the light collecting efficiency with only one direction. Thus, the reflecting device 20 of the third embodiment can be cooperatively used with the single-axis tracking system, or the reflecting device 20 also can be aligned along a north-south direction and fixed for not tracking the sunlight. In addition, as shown in FIG. 6, in the third embodiment, the reflecting devices 20 are only disposed at the two sides of the light energy conversion unit 10. Therefore, a plurality of the light energy conversion units 10 and a plurality of the reflecting devices 20 can be disposed side by side, so as to build up to a light energy conversion system having a large area.

### Fourth Embodiment

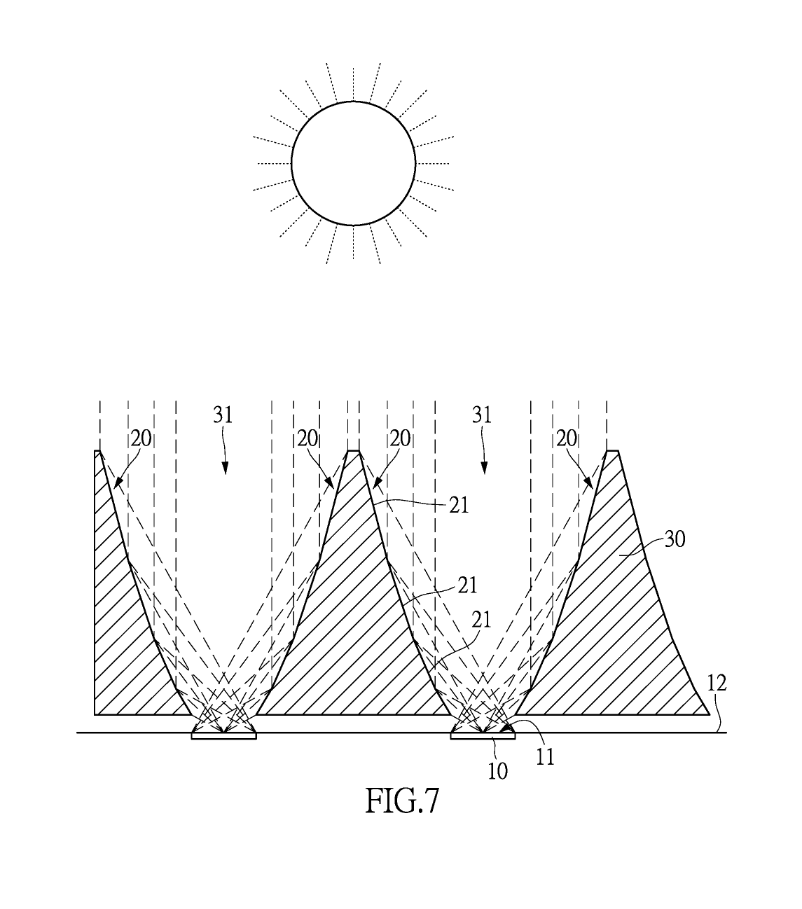

Please refer to FIG. 7. The manufacturing method of the reflecting device 20 is modified in the fourth embodiment. As shown in FIG. 7, the solar collector device of the fourth embodiment includes a base 30, a plurality of light energy conversion units 10, and a plurality of sunken grooves 31 and reflecting devices 20 disposed on the base 30. Wherein, each of the sunken grooves 31 penetrates from an upper surface to a lower surface of the base 30, and the plurality of light energy conversion units 10 are disposed at an opening of each of the sunken grooves 31 located on the base 30. Simultaneously, the plurality of reflecting devices 20 is respectively disposed at the plurality of sunken grooves 31 having two side walls. A material of the base 30 is selected from a group consisting of foam, plastic, wood, metal, composite material (such as glass fiber reinforced material), and combinations thereof. The material is selected from an easy-to-shape material. The reflective surface 20 of the plurality of reflecting devices 20 is directly formed on the side wall of each of the sunken grooves 31, and a reflective layer (e.g., reflective film, reflective sheet, or plating layer) is then disposed at the side wall, so as to form the plurality of reflective surfaces 21.

The reflecting device 20 of the fourth embodiment is manufactured using a different method, but the fundamentals and functions in the fourth embodiment are the same as the abovementioned fundamentals and functions of the reflecting device. The technical means of these embodiments can be used in combination.

### Fifth Embodiment

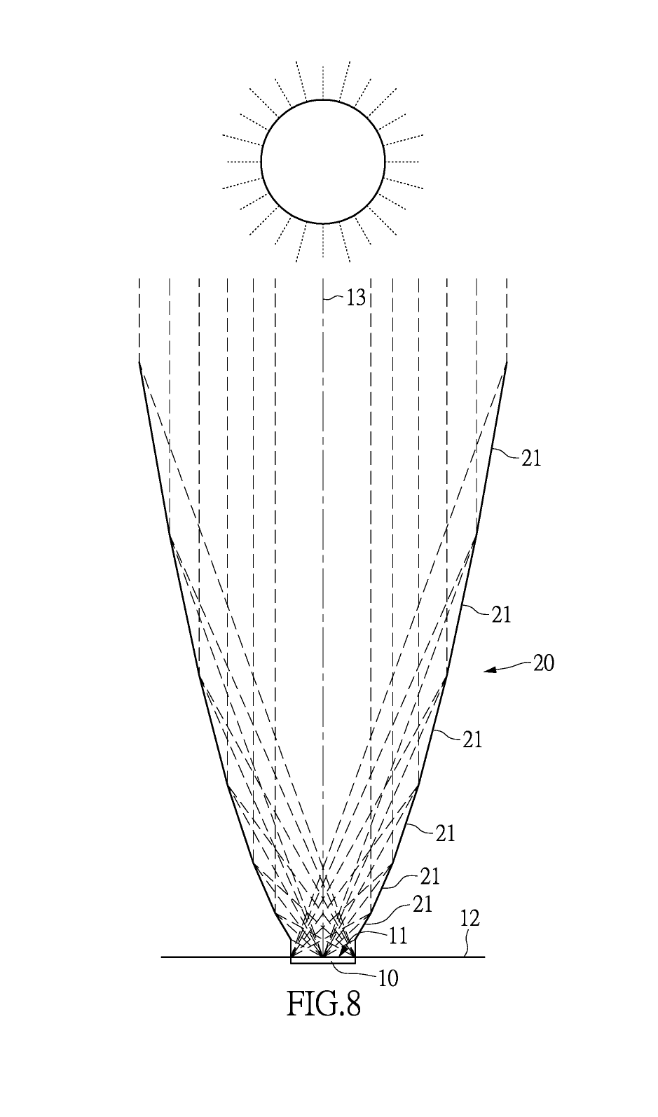

Please refer to FIG. 8. Each of the reflective surfaces 21 of the reflecting device 20 in the fifth embodiment reflects the sunlight rays and forms the projection area on the light receiving surface 11 of the light energy conversion unit 10, and the projection area only covers a half of the light receiving surface 11. As shown in FIG. 8, the reflective light of each of the reflective surfaces 21 of the reflecting device 20 at a right side of a centerline 13 of the light receiving surface 11 projects onto an area between a left edge and the centerline 13 of the light receiving surface 11. The reflective light of each of the reflective surfaces 21 of the reflecting device 20 at the left side of the centerline 13 forms the projection area which covers the area between the right edge and the centerline 13 of the light receiving surface 11. Hence, the area located at the two sides of the centerline 13 of the light receiving surface 11 is respectively covered by the sunlight rays projecting on the reflective surfaces 21 of the different reflecting devices 20.

The different reflecting devices 20 of the solar collector device in this embodiment can be utilized to respectively cover the different areas of the light receiving surface 11 of the light energy conversion unit 10, so as to meet the light collecting efficiency. By this way, the light intensity entering into each of the areas of the light receiving surface 11 of the light energy conversion unit 10 is more even.

In this embodiment, the inclination angle and height of each of the reflective surfaces 21 of the reflecting device 20 of the solar collector device in this instant disclosure can be further arranged to let each of the reflective surfaces 21 respectively reflect the sunlight rays in the different projection areas on the light receiving surface 11 of the light energy conversion unit 10. The projection area formed by each of the reflective surfaces 21 can cooperatively cover the whole area of the light receiving surface 11. That is to say, the light receiving surface 11 can be divided into a plurality of projection areas, the height and inclination angle of each of the reflective surfaces 21 are respectively arranged to be able to project the sunlight rays in each of the different areas, such that the reflective light of the reflecting device 20 can evenly project in every corner on the light receiving surface 11, or the projection area formed by the reflective light of each of the reflective surfaces 21 can be partly overlapped, so as to locally increase the amount of receiving light by the light receiving surface 11.

### Sixth Embodiment

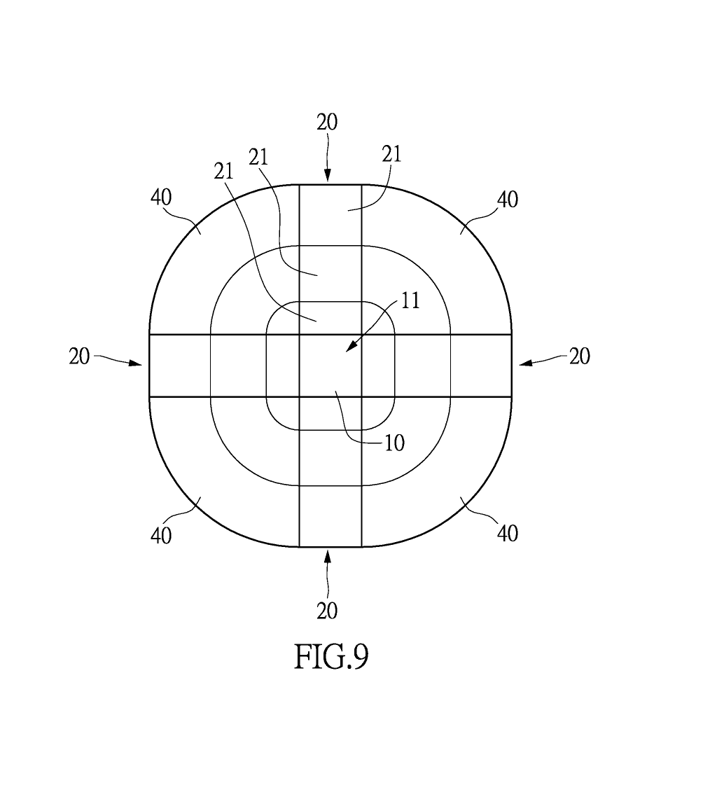

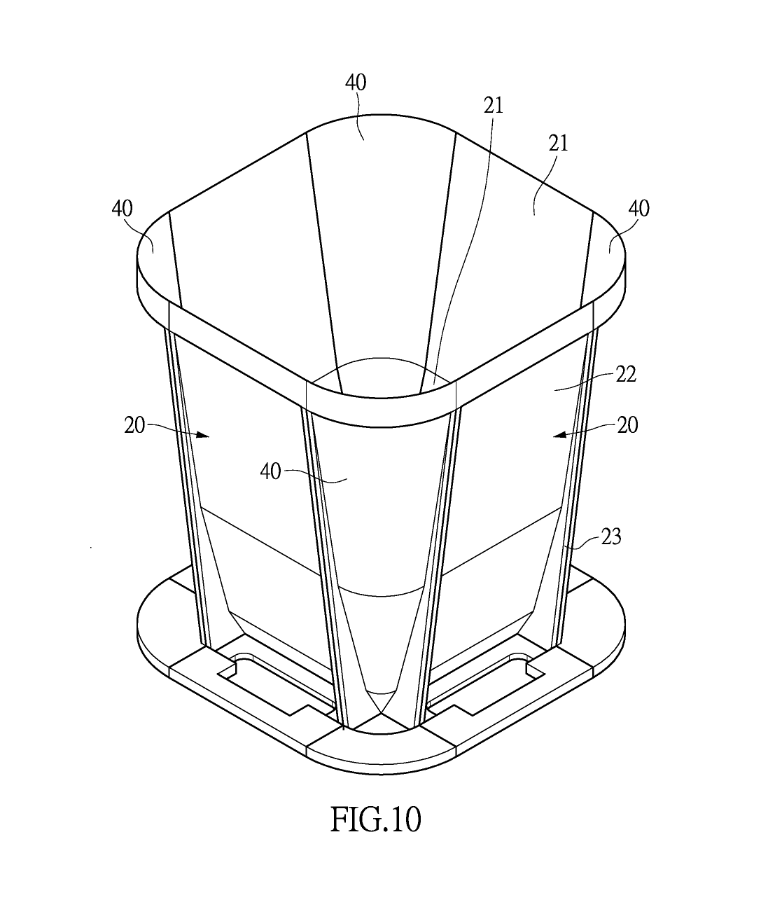

Please refer to FIGS. 9 and 10. The solar collector device of the sixth embodiment includes a light energy conversion unit 10, a plurality of reflecting devices 20, and a plurality of auxiliary collector devices 40. The structures and characteristics of the light energy conversion unit 10 and the reflecting device 20 are identical to each of the abovementioned embodiments. Thus, it is not repeated here again.

In this embodiment, the reflecting device 20 is respectively aligned and disposed at four sides of the light receiving surface 11 of the light energy conversion unit 10, when each of the reflecting devices 20 is observed by a plan view, that is represented a cross shape. An auxiliary collector device 40 is further disposed in a gap between each of the two adjacent reflecting devices 20 in this embodiment. The auxiliary collector device 40 of this embodiment is an arc-shaped reflector connected between two adjacent sides of the two adjacent reflecting devices 20. A cross-sectional shape of the reflector of the auxiliary collector device 40 has an arc-curve, and the reflector of each of the auxiliary collector devices 40 has a certain inclination angle that the sunlight rays can be reflected to project on the light receiving surface 11 of the light energy conversion unit 10 by a certain inclination angle. The sunlight rays not in the area covered by the reflecting device 20 can be reflected onto the light receiving surface 11 of the light energy conversion unit 10 via the auxiliary collector device 40, so as to upgrade the overall amount of receiving light.

### Seventh Embodiment

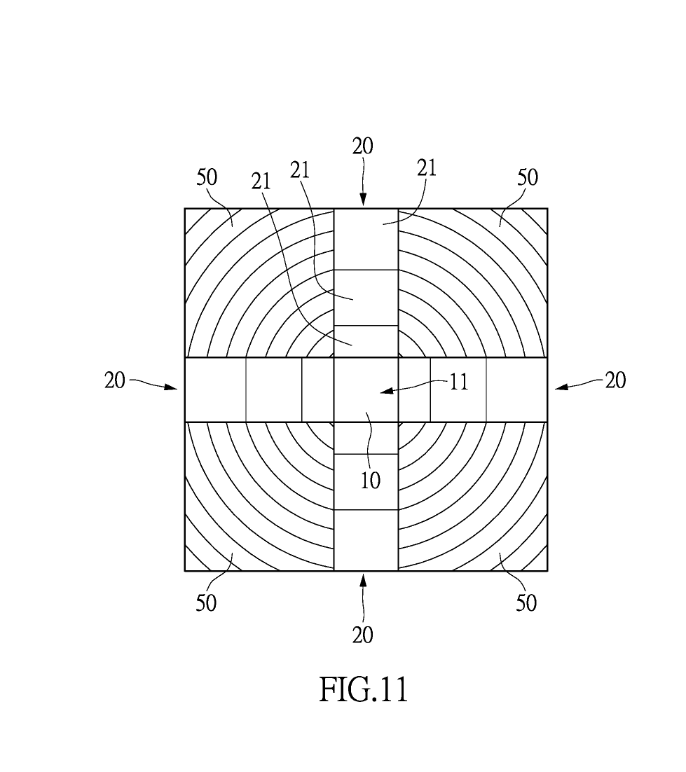

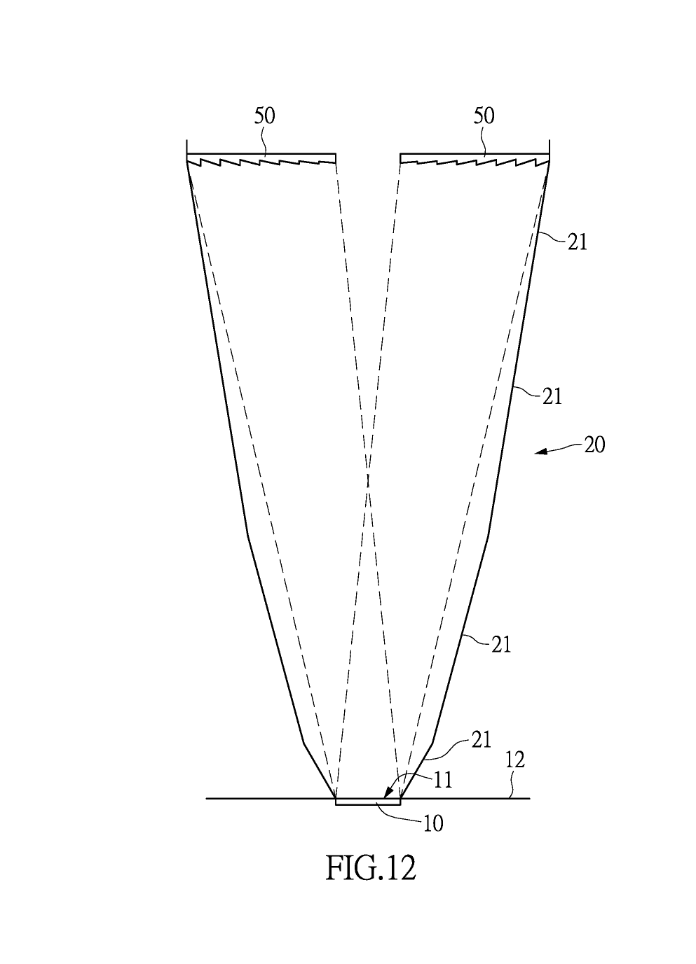

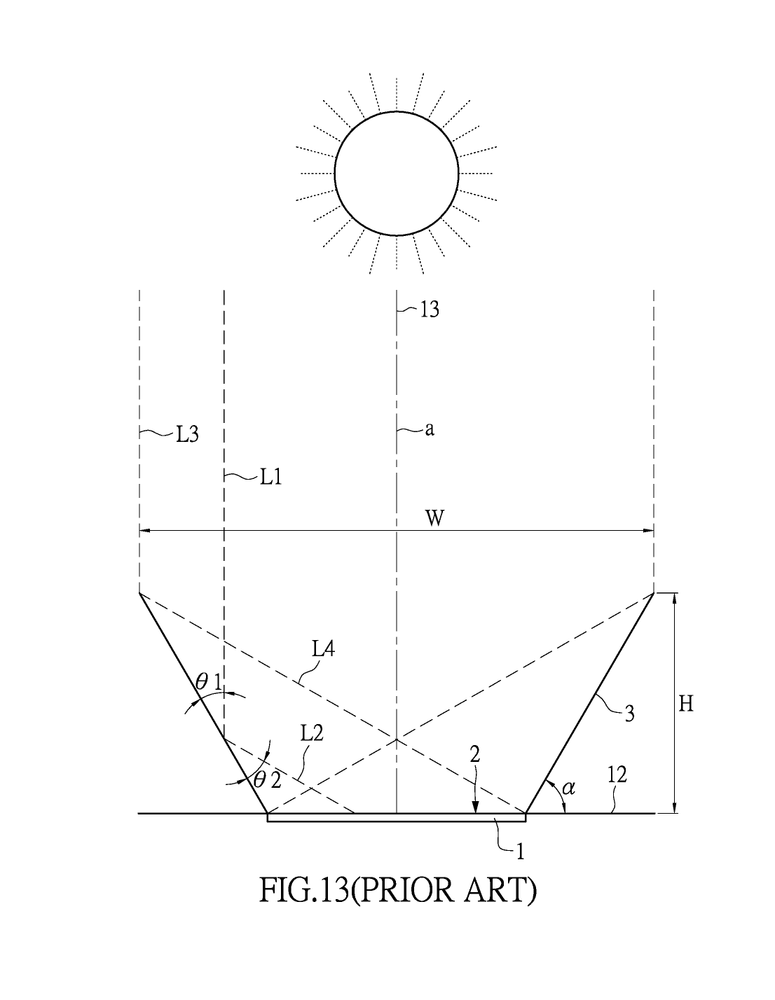

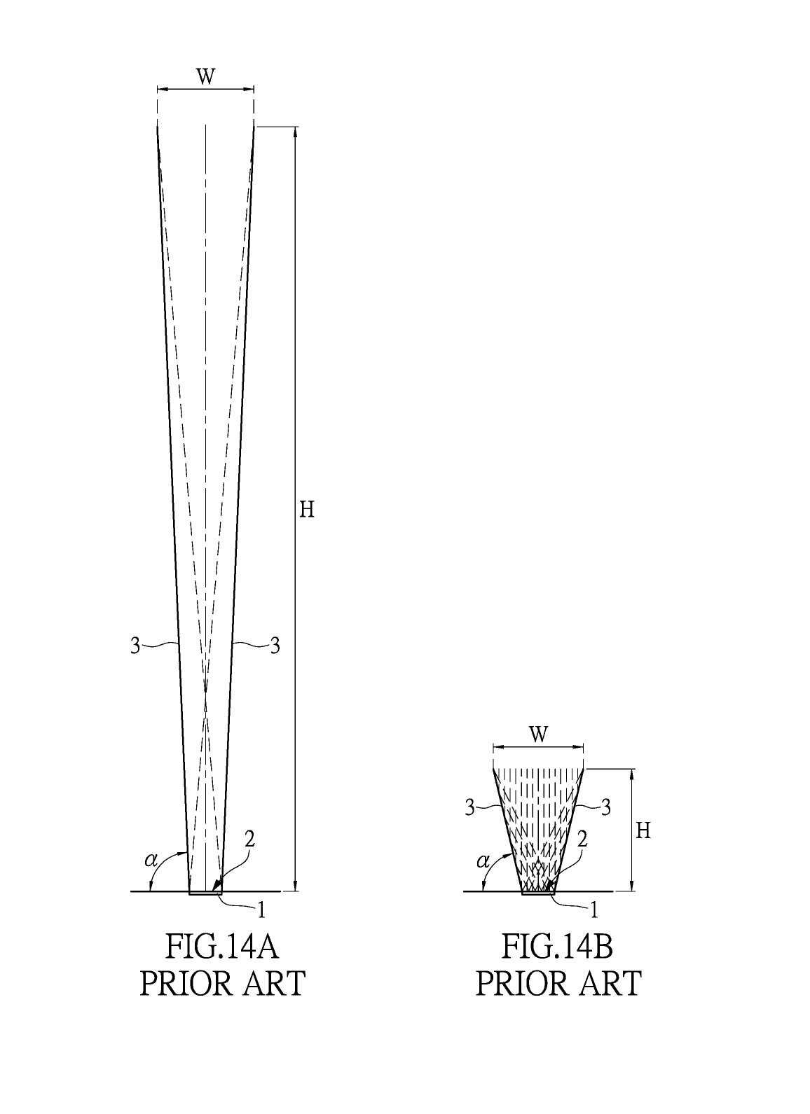

Please refer to FIGS. 11 and 12. The seventh embodiment is similar to the sixth embodiment is that, an auxiliary collector device 40 is disposed in a gap between each of the two adjacent reflecting devices 20. The auxiliary collector device 40 of this embodiment is a plurality of condenser lenses 50, each of the condenser lenses 50 covers above the gap between each of the two adjacent reflecting devices 20, so as to reflect the sunlight rays projecting on the gap onto the light receiving surface 11 of the light energy conversion unit 10. In this embodiment, the four condenser lenses 50 are formed by dividing four corners of an integral fresnel lens. Each of the condenser lenses 50 can respectively project the sunlight rays passing through the condenser lenses 50 or focus on the light receiving surface 11 of the light energy conversion unit 10, so as to increase the overall amount of receiving light by the light energy conversion unit 10 of the solar collector device.

### Efficacy of Embodiments

This instant disclosure has advantages in that, since the reflecting device is composed of the plurality of reflective surfaces having different inclination angles, the reflecting device of this instant disclosure can overcome the conventional reflective plate having the reflective surfaces with the same inclination angle, a width of the top opening of the reflective plate is limited by the included angle between the reflective plate and the light receiving surface, and limitation of the width of light receiving surface of the light energy conversion unit, to achieve an increase of the width of the top opening of the reflective plate under the limited heights of reflective plate, so as to increase an area of effective collecting area, and further enhance a light collection efficiency of the solar collector device.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

What is claimed is:

1. A solar collector device used for concentrating sunlight rays to a light energy conversion unit to increase entering amount of light of the light energy conversion unit, the light energy conversion unit having a light receiving surface located on a reference plane, and the solar collector device comprising:
at least two reflecting devices being used for reflecting the sunlight rays on the light receiving surface, the two reflecting devices being respectively disposed at two opposite sides of the light receiving surface, the two reflecting devices respectively having a plurality of reflective surfaces which are connected with each other, wherein the reflective surfaces have different inclination angles between each of the reflective surfaces and the reference plane, and each of the inclination angles of the reflective surfaces is arranged to let each of the reflective surfaces be able to reflect the sunlight rays on the light receiving surface of the light energy conversion unit.

2. The solar collector device as claimed in claim 1, wherein the plurality of reflective surfaces of each of the reflecting devices respectively have different heights and different inclination angles between each of the reflective surfaces and the reference plane, and the heights and the inclination angles of each of the reflective surfaces are arranged to let each of the reflective surfaces be able to reflect the sunlight rays in an identical projection area of the light receiving surface of the light energy conversion unit.

3. The solar collector device as claimed in claim 2, wherein the plurality of reflective surfaces of each of the reflecting devices project reflected lights reflected from the sunlight rays in the projection area generated on the light receiving surface, and the projection area at least covers a range from a side edge to a central location of the light receiving surface.

4. The solar collector device as claimed in claim 2, wherein the plurality of reflective surfaces project the reflected lights reflected from the sunlight rays in the projection area generated on the light receiving surface, and the projection area covers all of the light receiving surface.

5. The solar collector device as claimed in claim 2, wherein the inclination angle between each of the reflective surfaces and the light receiving surface ranges from 45 to 90 degrees, in the plurality of reflective surfaces of each of the reflecting devices, the reflective surface closest to the light receiving surface has a smallest inclination angle, the reflective surface remotest from the light receiving surface has a largest inclination angle, the inclination angle of each of the reflective surfaces is smaller than the inclination angle between the next reflective surface adjacent to the reflective surface and the reference plane, and the inclination angle of each of the reflective surfaces is equal or smaller than the inclination angle between a light reflection path of the next reflective surface adjacent to the reflective surface and the reference plane.

6. The solar collector device as claimed in claim 5, wherein the inclination angle of the plurality of reflective surfaces of each of the reflecting device meets the following relationship: αₙ<αₙ₊₁, and αₙ≦θₙ₊₁, and 45°<α<90°, wherein α represents the relative inclination angle between each of the reflective surfaces and the reference plane, θ represents the relative inclination angle between the light reflection path generated by the sunlight rays projecting on each of the reflective surfaces and the reference plane, n represents an order of an arrangement in a direction from each of the reflective surfaces in the reflecting device close to the light receiving surface away from the light receiving surface, and n is a positive integer which is larger than or equal to 1 and smaller than the total amount of the reflective surfaces in each of the reflecting devices.

7. The solar collector device as claimed in claim 5, wherein the reflecting device includes two first reflecting devices disposed at two opposite sides of the light receiving surface, and two second reflecting devices disposed at the other two opposite sides of the light receiving surface, the first reflecting device and the second reflecting device are arranged in a cross shape.

8. The solar collector device as claimed in claim 7, wherein an auxiliary collector device is respectively disposed at an interval position between each of the first reflecting devices and the adjacent second reflecting device.

9. The solar collector device as claimed in claim 8, wherein the auxiliary collector device is a plurality of arc-shaped reflectors connected between two adjacent sides of the adjacent first and second reflecting devices.

10. The solar collector device as claimed in claim 8, wherein the auxiliary collector device is a plurality of condenser lenses disposed above the first reflecting device and the second reflecting device.

11. The solar collector device as claimed in claim 1, wherein the plurality of reflective surfaces of each of the reflecting devices respectively have different heights and different inclination angles between each of the reflective surfaces and the reference plane, and the height of each of the reflective surfaces and the relative inclination angle are arranged to let each of the reflective surfaces be able to reflect the sunlight rays in different projection areas on the light receiving surface of the light energy conversion unit, and the projection area generated by each of the reflective surfaces cooperatively cover all of the area of the light receiving surface.

12. The solar collector device as claimed in claim 1, wherein each of the reflecting devices is composed of at least one board member and at least one supporting member disposed at a backside of the board member, and the plurality of the reflective surfaces are disposed at a front side of the board member.

13. The solar collector device as claimed in claim 1, wherein each of the reflecting devices is disposed on a base which defines a plurality of sunken grooves, and a reflective material is disposed at a side surface of the sunken groove to form the plurality of reflective surfaces of the reflecting device.

14. The solar collector device as claimed in claim 1, wherein the light energy conversion unit is a solar cell or a photothermal conversion device.
